(19) United States
(12) Patent Application Publication
(10) Pub. No.: US 2026/0305309 A1
(43) Pub. Date: Oct. 1, 2026

(54) AIR-GAPPED VIAS

(71) Applicant: INTERNATIONAL BUSINESS MACHINES CORPORATION, Armonk, NY (US)

(72) Inventors: Kamal Rudra, Albany, NY (US); Ruilong Xie, Niskayuna, NY (US); Lawrence Alfred Clevenger, Saratoga Springs, NY (US); Kisik Choi, Watervliet, NY (US); Yann Mignot, Slingerlands, NY (US); Koichi Motoyama, Clifton Park, NY (US)

(21) Appl. No.: 19/095,717

(22) Filed: Mar. 31, 2025

(51) Int. Cl. H10W 20/41; H10W 20/00; H10W 20/42; H10W 20/46

(52) U.S. Cl. CPC H10W 20/435; H10W 20/072; H10W 20/077; H10W 20/42; H10W 20/427; H10W 20/46

(57) ABSTRACT

Devices and methods of making the same include a first conductive line on an underlying layer. A first via is on the first conductive line. An interlayer dielectric is around the first via, with an air gap between the interlayer dielectric and the first via.

### BACKGROUND

The present invention generally relates to semiconductor device manufacturing and, more particularly, to the formation of air-gapped vias.

Conductive interconnects, such as metal lines and vias, are used to provide power and signal communications to semiconductor devices. Because of the small device sizes used in modern semiconductor fabrication, the conductive interconnects scale similarly. This can produce unwanted parasitic capacitances between neighboring structures. This occurs due to the natural ability of any two conductive objects, separated by an insulating material or space (dielectric), to store electrical charge. It is an inherent property of circuit components, PCB traces, semiconductor devices, and wiring. The parasitic capacitance between neighboring conductive structures is influenced by the distance between the structures as well as by the dielectric that separates them.

Parasitic capacitances can cause problems for electronic circuits. For example, in high-frequency circuits, parasitic capacitance can distort signals be causing unintended coupling between different parts of the circuit. This can limit frequency response and reduce system performance. These capacitances can also cause unwanted feedback and oscillations, as a capacitance in a circuit with an inductance will oscillate. This results in wasted power and can interfere with logic timing.

### SUMMARY

A device includes a first conductive line on an underlying layer. A first via is on the first conductive line. An interlayer dielectric is around the first via, with an air gap between the interlayer dielectric and the first via.

A device includes parallel conductive lines on an underlying layer, including a first conductive line adjacent to a second conductive line. An interlayer dielectric is over the parallel conductive lines. A first via is within the interlayer dielectric and above the conductive lines. An air gap is between the interlayer dielectric and the first via, extending between the first conductive line and the second conductive line.

A method of forming air-gapped vias includes forming a conductive line with a via on an underlying layer. A spacer is conformally deposited on the conductive line and via. An interlayer dielectric is formed over the spacer, with a top surface of the via exposed. The spacer is etched away, leaving an air gap between the interlayer dielectric and the via.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view of a step in the fabrication of a device with air-gapped vias, in accordance with an embodiment of the present invention;

FIG. 2 is a set of cross-sectional views showing a step in the fabrication of a device with air-gapped vias, where a spacer is formed and patterned over a set of parallel conductive lines and conductive vias, in accordance with an embodiment of the present invention;

FIG. 3 is a set of cross-sectional views showing a step in the fabrication of a device with air-gapped vias, where an interlayer dielectric is formed over the conductive lines and the spacer, in accordance with an embodiment of the present invention;

FIG. 4 is a set of cross-sectional views showing a step in the fabrication of a device with air-gapped vias, where the spacer is selectively etched away, leaving air gaps around the conductive lines and the vias, in accordance with an embodiment of the present invention;

FIG. 5 is a set of cross-sectional views showing a step in the fabrication of a device with air-gapped vias, where a cap is formed over the interlayer dielectric and the vias, partially filling the air gaps, in accordance with an embodiment of the present invention;

FIG. 6 is a cross-sectional view of an alternative embodiment of a device with air-gapped vias, where the interlayer dielectric fully fills the gaps between the conductive lines before the spacer is removed, in accordance with an embodiment of the present invention;

FIG. 7 is a cross-sectional view of an alternative embodiment of a device with air-gapped vias, where the interlayer dielectric pinches off in the gaps between the conductive lines even in regions without a spacer, in accordance with an embodiment of the present invention;

FIG. 8 is a cross-sectional view of an alternative embodiment of a device with air-gapped vias, where the spacer was formed over only one via and its neighboring conductive lines, in accordance with an embodiment of the present invention;

FIG. 9 is a cross-sectional view of an alternative embodiment of a device with air-gapped vias, where the spacer was formed over only one via without reaching its neighboring conductive lines, in accordance with an embodiment of the present invention;

FIG. 10 is a cross-sectional view of an alternative embodiment of a device with air-gapped vias, where the spacer was formed over only one via and where the interlayer dielectric fully fills the gaps between the conductive lines before the spacer is removed, in accordance with an embodiment of the present invention; and

FIG. 11 is a block/flow diagram of a method for forming a device with air-gapped vias, in accordance with an embodiment of the present invention.

### DETAILED DESCRIPTION

The capacitance of conductive interconnects can be controlled by the use of air gaps in the surrounding dielectric material. The dielectric constant of vacuum (or air) is substantially lower than silicon dioxide, the most commonly used passivating dielectric material. While low-k dielectric materials are available to reduce parasitic capacitance in some circumstances, even these materials cannot provide as low a dielectric constant as an air gap, and forming such low-k dielectric materials with sufficient quality and reliability for production can be challenging, as they can be easily damaged by subsequent processing steps.

Conductive interconnects can therefore be formed with small dimensions using a subtractive process that provides air gaps, particularly around top vias. The air gaps can be implemented in a post-processing stage, so that vias with air gaps can be selectively defined after the conductive structures have already been formed. The air gaps furthermore provide exposure to the sidewalls of the top vias, so that overlying conductive interconnects can make lower-resistance contact to the top vias.

Vias according to the present embodiments may help to scale technology nodes to 2nm and below. The air-gapped vias may be used for critical path structures, such as clock signal lines. Such structures can be located using timing closure analysis.

Referring now to FIG. 1, a top-down view of a step in the fabrication of air-gapped interconnects, identifying a set of cross-sectional views that are used below to illustrate particular features of the present embodiments. A set of conductive lines 104 are formed on an underlying layer 102. In some embodiments the conductive lines 104 may be formed in parallel.

Some of the conductive lines 104 further include vias 106 that extend vertically (out of the page) from the top surface of the conductive lines 104. A spacer perimeter 108 is shown that covers at least one of the vias 106. As will be described in greater detail below, a spacer is formed in the spacer perimeter 108 to create a space between an interlayer dielectric and the conductive lines 104 and vias 106. The spacer is then selectively etched away, leaving an air gap on structures within the spacer perimeter 108. The spacer perimeter 108 may cover some or all of the vias 106, and may in some cases leave some vias 106 outside the perimeter. Those vias 106 which are within the spacer perimeter 108 will have an air gap, while those outside may not. As will be described in greater detail below, varying the position of the spacer perimeter 108 can produce a wide variety of different air gap embodiments.

The underlying layer 102 may be, for example, a device layer that includes one or more circuit components. The circuit components may include active components, such as transistors, and/or passive components, such as capacitors, inductors, resistors, and transmission lines. The underlying layer 102 may include a passivating dielectric formed from, e.g., silicon dioxide or any other appropriate dielectric material, with conductive interconnects exposed at a top surface of the underlying layer 102. The conductive lines 104 may make electrical contact with the exposed conductive interconnects to provide power and/or signal communications to the devices of the underlying layer 102. In some cases, the underlying layer 102 may include one or more layers of additional conductive interconnects on top of the device layer. These layers of conductive interconnects may form a back-end-of-line structure that can be used to supply power and signal communication to the device layer.

The conductive lines 104 may be formed from any appropriate conductive material. Copper and ruthenium are particularly contemplated, but other suitable conductive materials may include, e.g., tungsten, nickel, titanium, molybdenum, tantalum, platinum, silver, gold, iridium, rhenium, rhodium, cobalt, and alloys thereof. The vias 106 may be formed from the same conductive material as the conductive lines 104 or may be formed from a different conductive material.

The conductive lines 104 may have an exemplary 4:1 aspect ratio and may be formed by photolithography or by a sidewall image transfer process. Thus the conductive lines 104 may have any appropriate thickness and any appropriate spacing from one another. In some cases, the conductive lines 104 may be cut to separate a given line into multiple colinear conductive lines. The vias 106 may be formed by etching back a tall conductive line according to a via pattern or by depositing additional conductive material in appropriate locations.

The top-down view identifies a set of cross-sections, including XX, Y₁Y₁, and Y₂Y₂. The XX cross-section cuts across multiple of the conductive lines 104, through the vias 105. The Y₁Y₁ cross-section cuts along the length of one of the conductive lines 104 that crosses through the spacer perimeter 108 and that includes a via 106. The Y₂Y₂ cross-section cuts along the length of another one of the conductive lines 104 that crosses through the spacer perimeter 108 but that does not include a via 106.

The structures shown in the different views of the figures may not be proportional or consistent between drawings. Thus, the dimensions and proportions shown in the drawings should not be regarded as limiting, but should instead be understood as instructive on questions relating to the relationships between the different structures.

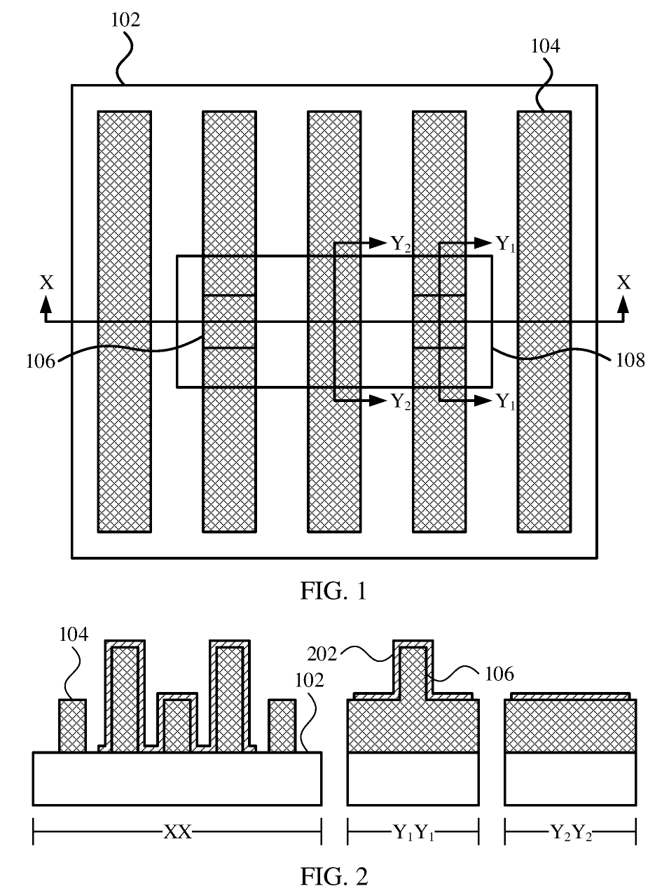

Referring now to FIG. 2, a set of cross-sectional views are shown of a step in the fabrication of a semiconductor device. The XX cross-section shows the conductive lines 104 with vias 106 extending above their top surface. A spacer 202 is formed over the vias 106. Exemplary spacer materials include Al₂O₃ and an organic double-layer protective coating (ODC). The spacer 202 may be formed to a thickness that will correspond to a dimension of the air gap, for example between about 1nm and about 5nm measured from a sidewall of the first via. In some embodiments, the spacer 202 may be formed over a first of the vias 106, over one of the conductive lines 104, and over a second of the vias 106 that is opposite to the first.

The spacer 202 may be formed from any appropriate material by conformal deposition, such as atomic layer deposition (ALD), followed by a patterning step that removes any spacer material outside of the spacer perimeter 108. Some misalignment between the spacer 202 and the conductive lines 104 can be tolerated, so high-precision fabrication processes such as extreme ultraviolet photolithography are not needed. For example, a mask may be formed that covers the spacer material in the spacer perimeter 108, followed by a selective etch that removes exposed spacer material. As used herein, the term “selective” in reference to a material removal process denotes that the rate of material removal for a first material is greater than the rate of removal for at least another material of the structure to which the material removal process is being applied.

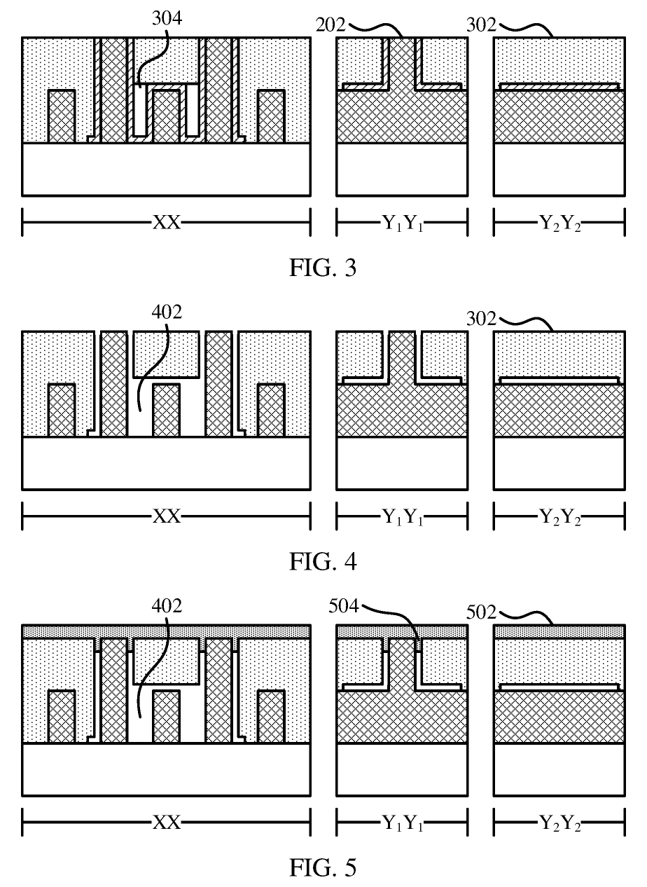

Referring now to FIG. 3, a set of cross-sectional views are shown of a step in the fabrication of a semiconductor device. An interlayer dielectric 302 is deposited over the conductive lines 104 and the spacer 202. Any appropriate dielectric material, such as silicon dioxide or a low-k dielectric material, may be used to form the interlayer dielectric 302, for example using a chemical vapor deposition (CVD) process.

The deposition may pinch off in the narrow gaps between adjacent conductive lines that are covered by the spacer 202, resulting in gaps 304. The thickness of the spacer 202 influences whether the interlayer dielectric 302 will pinch off, as larger spacer thickness causes there to be less space open between the conductive lines. In some cases the vertical thickness of the interlayer dielectric 302 may be different in regions with the spacer 202 as compared to regions without the spacer 202. In particular, the presence of the spacer 202 causes the vertical thickness to be smaller in those regions.

The dielectric material of the interlayer dielectric 302 may be polished back after deposition to expose top surfaces of the spacer 202. This may be performed using a chemical mechanical planarization (CMP) process. CMP is performed using, e.g., a chemical or granular slurry and mechanical force to gradually remove upper layers of the device. The slurry may be formulated to be unable to dissolve, for example, the conductive material, resulting in the CMP process’s inability to proceed any farther than that layer.

Referring now to FIG. 4, a set of cross-sectional views are shown of a step in the fabrication of a semiconductor device. The spacer 202 is etched away, for example using an isotropic wet or vapor etch that removes spacer material from underneath the interlayer dielectric 302. This produces air gap 402 around the conductive lines 104 and vias 106. In embodiments where this step and subsequent steps are performed in a vacuum, the air gap 402 may be a vacuum gap. The term “air gap” as used herein is intended to include vacuum gaps as well as gaps that include air. In some areas the air gap 402 may have same thickness as the spacer 202, while in other areas the thickness of the air gap 402 may be greater than the thickness of the spacer 202. As shown in the Y₁Y₁ and Y₂Y₂ views, the air gap 402 may be localized on the top surfaces of the conductive lines 104. The resulting air gap 402 may thus be around a first of the vias 106, around one of the conductive lines 104, and around a second of the vias 106 opposite to the first.

In some embodiments, the spacer 202 may be formed from an aluminum oxide, with the etch being a highly isotropic, selective wet etch. In some embodiments, the spacer 202 may be formed from titanium nitride or titanium oxide, with the etch being an SC1 clean that includes a solution of ammonium hydroxide, hydrogen peroxide, and deionized water. The material of the spacer 202 is thereby dissolved into the etchant and may then be washed away, leaving the air gap 402 unobstructed.

Referring now to FIG. 5, a set of cross-sectional views are shown of an optional step in the fabrication of a semiconductor device. A dielectric cap 502 is formed over the interlayer dielectric 302 using any appropriate dielectric material that is selectively etchable with respect to the material of the interlayer dielectric and the vias 106. The dielectric cap 502 partially fills the air gap 402 with dielectric plugs 504 that extend between the first via and the interlayer dielectric. The dielectric cap 502 may have an exemplary thickness between about 2nm and about 6nm. From this stage the dielectric cap 502 may be selectively etched to expose vias 106 as needed for providing electrical connections to overlying layers.

In some embodiments, the formation of the dielectric cap 502 may be omitted and a next layer of metal, such as ruthenium, may be deposited to form electrical connections with the via 106. In such embodiments, the deposited metal may similarly partially fill the air gap 402, thereby increasing contact area between the next metal layer and the via 106.

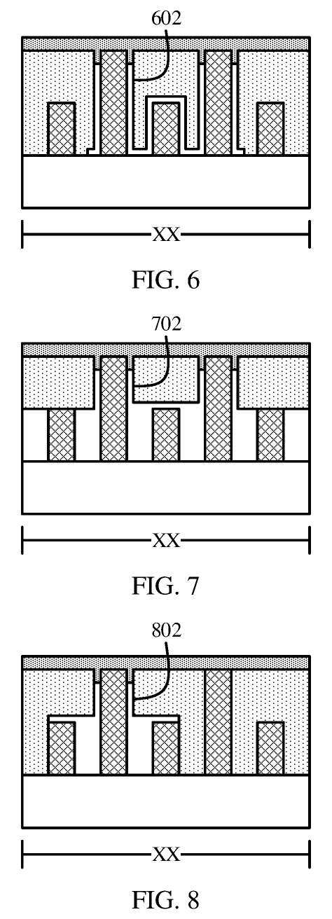

Referring now to FIG. 6, a cross-sectional view along cross-section XX is shown of an alternative embodiment. This embodiment may be formed by using a spacer 202 which is thin enough such that the deposition of interlayer dielectric 302 does not pinch off, instead completely filling the gap 304. Alternatively a deposition process and interlayer dielectric material may be selected such that conformal deposition is possible even in a narrow gap, for example using atomic layer deposition. The resulting air gap 602 has a consistent width around the conductive lines 104 and the vias 106.

Referring now to FIG. 7, a cross-sectional view along cross-section XX is shown of an alternative embodiment. In this embodiment, the spacer 202 may be extended laterally to cover multiple additional conductive lines 104, such that the interlayer dielectric pinches off between them. The resulting air gap 702 extends between conductive lines 104 as well as around the vias 106. This embodiment may be formed with a spacer that covers adjacent vias and a metal line between them. Additional metal lines that lack the spacer may still pinch off during the formation of the interlayer dielectric material, leaving an air gap between them.

Referring now to FIG. 8, a cross-sectional view along cross-section XX is shown of an alternative embodiment. In this embodiment the spacer 202 stops on the conductive lines 104, producing an air gap 802 around only a single via 106.

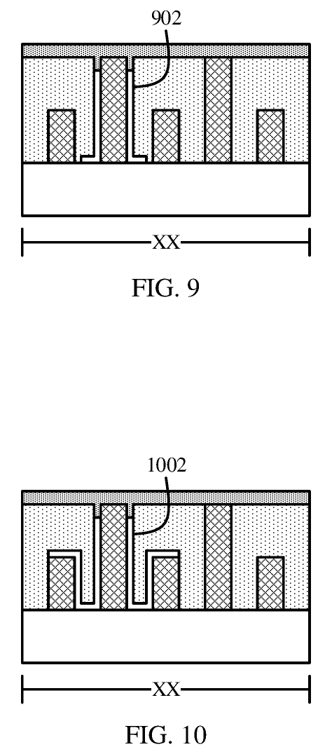

Referring now to FIG. 9, a cross-sectional view along cross-section XX is shown of an alternative embodiment. In this embodiment the spacer 202 stops between the conductive lines 104, producing an air gap 902 around only a single via 106.

Referring now to FIG. 10, a cross-sectional view along cross-section XX is shown of an alternative embodiment. In this embodiment the spacer 202 stops on the conductive lines 104, producing an air gap 1002 around only a single via 106. This embodiment may be formed by using a spacer 202 which is thin enough such that the deposition of interlayer dielectric 302 does not pinch off, instead completely filling the gap 304. Alternatively a deposition process and interlayer dielectric material may be selected such that conformal deposition is possible even in a narrow gap, for example using atomic layer deposition. The resulting air gap 1002 has a consistent width around the conductive lines 104 and the vias 106. In some cases, the spacer 202 in this embodiment may be extended past the neighboring conductive lines 104, so that the air gap 1002 exists on both sides of the conductive lines 104.

Any combination of these embodiments may be created on a single device, for example by selecting positions and sizes of spacer 202 to create air gaps in any appropriate positions. The capacitance of the vias 106 and the conductive lines 104 can thereby be tuned, with air gaps providing lower capacitances than when the spaces around these structures are completely filled by the interlayer dielectric.

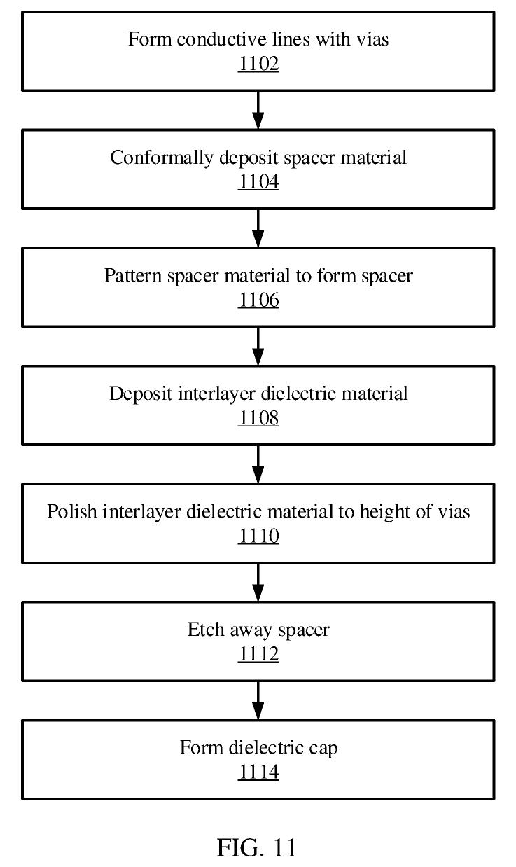

Referring now to FIG. 11, a method for forming air-gapped vias is shown. Block 1102 forms the conductive lines 104 with vias 106. These conductive lines may be formed by any appropriate process, such as by a subtractive process where a layer of conductive material is deposited and subsequently patterned using photolithography.

Block 1104 conformally deposits spacer material, for example using ALD or CVD, on the conductive lines 104 and the vias 106. Block 1106 then patterns the spacer material to form a spacer 202 in a selected region of the device. Block 1108 deposits interlayer dielectric material over and around the conductive lines 104, vias 106, and spacer 202. In some cases the deposition of the interlayer dielectric material may pinch off in the spaces between the conductive lines 104 where the spacer 202 is present, leaving gaps 304. In other cases the deposition of the interlayer dielectric material may fill those spaces, leaving no gaps.

Block 1110 polishes the deposited interlayer dielectric material down to the level of the vias 106, exposing a top surface of the vias 106 and a top edge of the sidewalls of the spacer 202. Block 1112 then etches away the spacer 202 using, e.g., a selective isotropic etch. This leaves air gap 402 behind. Block 1114 then deposits dielectric cap 502, which pinches off in the air gap 402 at the vias 106, forming dielectric plugs 504.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of air-gapped vias (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A device, comprising:
a first conductive line on an underlying layer;
a first via on the first conductive line; and
an interlayer dielectric around the first via, with an air gap between the interlayer dielectric and the first via.

2. The device of claim 1, further comprising a dielectric cap over the first via and the interlayer dielectric, including a dielectric plug that extends between the first via and the interlayer dielectric.

3. The device of claim 1, wherein the air gap extends down along the first conductive line to the underlying layer.

4. The device of claim 1, further comprising a second conductive line next to the first conductive line, wherein the air gap extends between the first conductive line and the second conductive line below the interlayer dielectric.

5. The device of claim 4, wherein the interlayer dielectric does not extend down between the first conductive line and the second conductive line.

6. The device of claim 4, wherein the interlayer dielectric extends down between the first conductive line and the second conductive line.

7. The device of claim 4, wherein the air gap extends between the interlayer dielectric and a top surface of the second conductive line.

8. The device of claim 4, further comprising:
a third conductive line next to the second conductive line, opposite to the first conductive line; and
a second via on the third conductive line, wherein the air gap extends between the second via and the interlayer dielectric.

9. The device of claim 1, wherein the air gap has a width between 1nm and 5nm measured from a sidewall of the first via.

10. A device, comprising:
a plurality of parallel conductive lines on an underlying layer, the plurality of parallel conductive lines comprising a first conductive line adjacent to a second conductive line;
an interlayer dielectric over the plurality of parallel conductive lines;
a first via within the interlayer dielectric and above the plurality of parallel conductive lines; and
an air gap between the interlayer dielectric and the first via, the air gap extending between the first conductive line and the second conductive line of the plurality of parallel conductive lines.

11. The device of claim 10, further comprising a dielectric cap over the first via and the interlayer dielectric, including a dielectric plug that extends between the first via and the interlayer dielectric.

12. The device of claim 10, wherein the air gap extends down along the first conductive line to the underlying layer.

13. The device of claim 10, wherein the interlayer dielectric does not extend down between the first conductive line and the second conductive line.

14. The device of claim 10, wherein the interlayer dielectric extends down between the first conductive line and the second conductive line.

15. The device of claim 10, wherein the air gap extends between the interlayer dielectric and a top surface of the second conductive line.

16. The device of claim 10, further comprising:
a second via on a third conductive line of the plurality of parallel conductive lines, wherein the air gap extends between the second via and the interlayer dielectric.

17. The device of claim 10, wherein the air gap has a width between 1nm and 5nm measured from a sidewall of the first via.

18. A method of forming air-gapped vias, comprising:
forming a conductive line with a via on an underlying layer;
conformally depositing a spacer on the conductive line and via;
forming an interlayer dielectric over the spacer, with a top surface of the via exposed; and
etching away the spacer, leaving an air gap between the interlayer dielectric and the via.

19. The method of claim 18, further comprising depositing a dielectric cap over the interlayer dielectric and the via, with a dielectric plug that extends between the via and the interlayer dielectric.

20. The method of claim 18, wherein forming the interlayer dielectric includes a deposition process that pinches off in a space between the conductive line and an adjacent conductive line, leaving a gap therebetween.
